(19) United States
(12) Patent Application Publication
(10) Pub. No.: US 2024/0224510 A1
(43) Pub. Date: Jul. 4, 2024

(54) FIELD-EFFECT TRANSISTOR AND INTEGRATED CIRCUIT DEVICE INCLUDING THE SAME

(71) Applicant: Samsung Electronics Co., Ltd., Suwon-si (KR)

(72) Inventors: Seunghee LEE, Suwon-si (KR); Jaekyeong JEONG, Seoul (KR); Seungwan SEO, Seoul (KR); Yongsuk TAK, Suwon-si (KR); Yurim KIM, Suwon-si (KR); Teawon KIM, Suwon-si (KR); Joohee JEONG, Seoul (KR)

(73) Assignees: Samsung Electronics Co., Ltd., Suwon-si (KR); IUCF-HYU (Industry-University Cooperation Foundation Hanyang University)., Seoul (KR)

(21) Appl. No.: 18/354,041

(22) Filed: Jul. 18, 2023

(30) Foreign Application Priority Data
Dec. 28, 2022 (KR) 10-2022-0187755

(51) Int. Cl. H10B 12/00

(52) U.S. Cl. CPC H10B 12/485; H10B 12/315; H10B 12/34

(57) ABSTRACT

A field-effect transistor includes an insulating barrier layer on a substrate, a gate electrode extending on the insulating barrier layer, a gate insulating layer covering opposite side surfaces and a top surface of the gate electrode, an oxide semiconductor layer on the gate insulating layer and including at least one metal element selected from indium (In) and zinc (Zn), and a source structure and a drain structure separated from each other, the source structure and the drain structure electrically connected to the oxide semiconductor layer. Each of the source structure and the drain structure includes an indium gallium tin oxide (IGTO) film on the oxide semiconductor layer, a conductive metal nitride film on the IGTO film, one of a source electrode and a drain electrode on the conductive metal nitride film, and a top capping layer on a top surface of one of the source electrode and the drain electrode.

### CROSS-REFERENCE TO RELATED APPLICATION

This application is based on and claims priority under 35 U.S.C. § 119 to Korean Patent Application No. 10-2022-0187755, filed on Dec. 28, 2022, in the Korean Intellectual Property Office, the disclosure of which is incorporated by reference herein in its entirety.

### BACKGROUND

Various example embodiments relate to a field-effect transistor and/or an integrated circuit device including the same. More particularly, various example embodiments relate to a field-effect transistor including an indium gallium zinc oxide (IGZO) semiconductor and/or an integrated circuit device including the field-effect transistor.

As the integration density of transistors increases with the down-scaling of semiconductor devices, leakage current is increasing due to a short-channel effect. To improve the leakage current, transistors using an oxide semiconductor having a low-leakage current characteristic are being developed.

### SUMMARY

Various example embodiments may provide a field-effect transistor having increased electrical characteristics and/or reliability by improving contact resistance. Alternatively or additionally, some example embodiments may provide an integrated circuit device including the same.

Various example embodiments are not limited to those mentioned above, and other aspects that have not been mentioned will be clearly understood by one of skill in the art from the description below.

According to an aspect of various example embodiments, there is provided a field-effect transistor.

The field-effect transistor includes an insulating barrier layer on a substrate, a gate electrode extending in one direction on the insulating barrier layer, a gate insulating layer covering opposite side surfaces of and a top surface of the gate electrode, an oxide semiconductor layer on the gate insulating layer and including at least one metal element selected from among indium (In) and zinc (Zn), and a source structure and a drain structure separated from each other, the source structure and the drain structure being configured to be electrically connected to the oxide semiconductor layer. Each of the source structure and the drain structure includes an indium gallium tin oxide (IGTO) film on the oxide semiconductor layer, a conductive metal nitride film on the IGTO film, one of a source electrode and a drain electrode on the conductive metal nitride film, and a top capping layer on a top surface of one of the source electrode and the drain electrode.

Alternatively or additionally according to various example embodiments, there is provided an integrated circuit device.

The integrated circuit device includes a substrate having a plurality active regions with a plurality of word line trenches defined in the substrate, the plurality of word line trenches extending in a first horizontal direction that is parallel with a top surface of the substrate, a transistor structure on the substrate and including a source structure and a drain structure, and a plurality of bit line structures on the substrate, the plurality of bit line structures extending in a second horizontal direction that is parallel with the top surface of the substrate and crosses the first horizontal direction. The transistor structure includes a gate insulating layer, an oxide semiconductor layer on the gate insulating layer and including at least one metal element selected from among In and Zn, and a source structure and a drain structure separated from each other, the source structure and the drain structure being configured to be electrically connected to the oxide semiconductor layer. Each of the source structure and the drain structure includes an IGTO film on the oxide semiconductor layer, a conductive metal nitride film on the IGTO film, one of a source electrode and a drain electrode on the conductive metal nitride film, and a top capping layer on a top surface of one of the source electrode and the drain electrode.

Alternatively or additionally according to various example embodiments, there is provided an integrated circuit device including a bit line extending in a first horizontal direction on a substrate, a word line extending on the bit line in a second horizontal direction that crosses the first horizontal direction, an oxide semiconductor layer including at least one metal element selected from among In and Zn, the oxide semiconductor layer extending in a vertical direction on the bit line and being separated from the word line by a gate insulating layer, a landing pad on the oxide semiconductor layer, a capacitor structure on the landing pad, and a transistor structure in an overlapping portion between the bit line and the word line. The transistor structure includes a source structure and a drain structure each having a sequential stack of an IGTO film, a conductive metal nitride film, one of a source electrode and a drain electrode, and a top capping layer.

### BRIEF DESCRIPTION OF THE DRAWINGS

Various example embodiments will be more clearly understood from the following detailed description taken in conjunction with the accompanying drawings in which:

FIG. 1 is a schematic cross-sectional view of a field-effect transistor according to various example embodiment;

FIGS. 2A to 2E are respectively schematic cross-sectional views of various structures, which a field-effect transistor may have according to various example embodiments;

FIGS. 3A and 3B are graphs showing results of measuring contact resistance, contact resistivity, and carrier concentration under process conditions of an indium gallium tin oxide (IGTO) film;

FIG. 4 is a graph showing values of contact resistivity of a conductive metal nitride film, which are measured with respect to the partial pressure of nitrogen and the thickness of a titanium nitride (TiN) film;

FIGS. 5A and 5B are respectively graphs showing results of measuring contact resistivity when a TiN film is not inserted into a source/drain structure and when the TiN film is inserted into the source/drain structure;

FIGS. 6A to 6C are respectively graphs showing results of measuring contact resistivity at different thicknesses of an IGTO film in a source/drain structure having a TiN film inserted thereinto;

FIG. 7 is a schematic circuit diagram of an integrated circuit device according to various example embodiments;

FIG. 8A is a layout diagram of an integrated circuit device according to some embodiments;

FIG. 8B is a cross-sectional view taken along line A1-A1′ in FIG. 8A;

FIG. 9A is a layout diagram of an integrated circuit device according to some embodiments;

FIG. 9B is a cross-sectional view taken along line A2-A2′ in FIG. 9A; and

FIG. 10 is a schematic circuit diagram of an integrated circuit device according to some embodiments.

### DETAILED DESCRIPTION OF VARIOUS EXAMPLE EMBODIMENTS

Hereinafter, some embodiments will be described with reference to the accompanying drawings. In the drawings, like reference characters denote like elements, and redundant descriptions thereof will be omitted.

As example embodiments allow for various changes and numerous embodiments, some specific example embodiments will be illustrated in the drawings and described in detail in the written description. However, this is not intended to limit embodiments to particular modes of practice, and it is to be appreciated that all changes, equivalents, and substitutes that do not depart from the spirit and technical scope of various example embodiments are encompassed in example embodiments. In the description of some example embodiments, certain detailed descriptions of the related art are omitted when it is deemed that they may unnecessarily obscure the essence of various example embodiments.

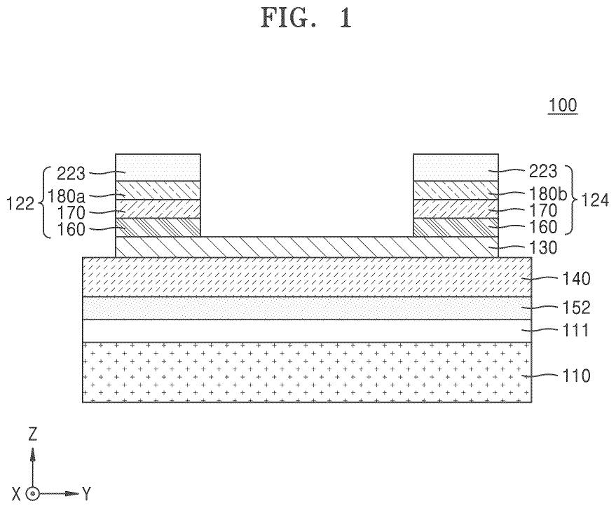

FIG. 1 is a schematic cross-sectional view of a field-effect transistor 100 according to some example embodiments. Referring to FIG. 1, a gate electrode 152 may extend in one direction (e.g., the Y direction in FIG. 1) on a substrate 110 upon which an insulating barrier layer 111 is formed. A gate insulating layer 140 may cover the opposite side surfaces and top surface of the gate electrode 152. An oxide semiconductor layer 130 may be on the gate insulating layer 140. For example, the oxide semiconductor layer 130 may include at least one metal element selected from among or from the group consisting of indium (In) and zinc (Zn). For example, the oxide semiconductor layer 130 may further include gallium (Ga). According to various example embodiments, a source structure 122 and a drain structure 124 may be electrically connected to the oxide semiconductor layer 130 and may be separated from each other. The source structure 122 may have a structure in which an indium gallium tin oxide (IGTO) film 160, a conductive metal nitride film 170, a source electrode 180a, and a top capping layer 223 are sequentially stacked. The drain structure 124 may have a structure in which the IGTO film 160, the conductive metal nitride film 170, a drain electrode 180b, and the top capping layer 223 are sequentially stacked.

In some example embodiments, the substrate 110 may include one or more of a glass material, a metal material, or a plastic material, such as polyethylene terephthalate (PET), polyethylene naphthalate (PEN), or polyimide. In some example embodiments, the substrate 110 may include one or more of Si, Ge, or a semiconductor material, such as SiGe, SiC, GaAs, InAs, or InP, and may or may not be doped with impurities.

According to various example embodiments, the source structure 122 and the drain structure 124 may include a conductive material. In some example embodiments, each of the source structure 122 and the drain structure 124 may include at least one selected from among or from the group consisting of W, WN, TiN, and TaN. In some example embodiments, each of the source structure 122 and the drain structure 124 may include doped polysilicon.

According to various example embodiments, the oxide semiconductor layer 130 may include an oxide semiconductor material including at least one metal element selected from among or from the group consisting of In, Ga, and Zn. For example, the oxide semiconductor layer 130 may include an amorphous semiconductor including oxygen (O) and at least one metal element selected from among or from the group consisting of In, Ga, and Zn.

According to various example embodiments, the gate insulating layer 140 may include at least one selected from the group consisting of silicon oxide, silicon nitride, silicon oxynitride, oxide/nitride/oxide (ONO), and a high-k dielectric film having a higher dielectric constant than the silicon oxide. The high-k dielectric film may include at least one material selected from among or from the group consisting of hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). Each of the terms “HfO”, “ZrO”, “LaO”, “TiO”, and “YO” used herein indicates a material composed of elements included in each term and is not a chemical equation representing stoichiometric relationships.

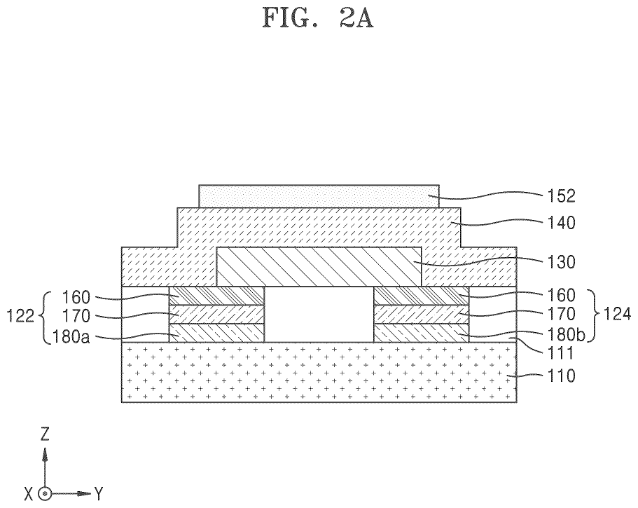

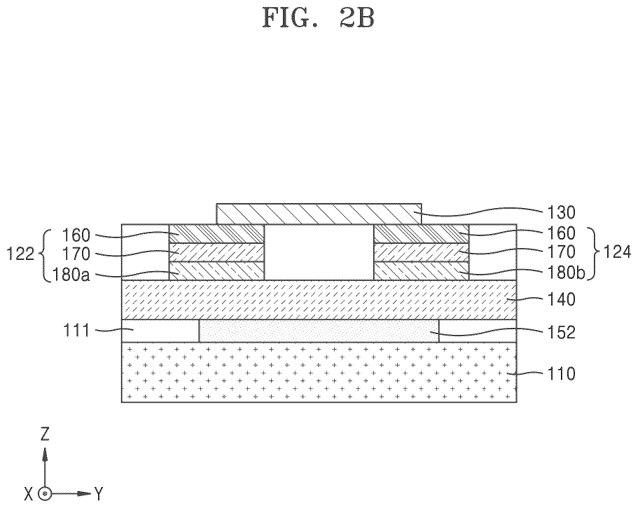

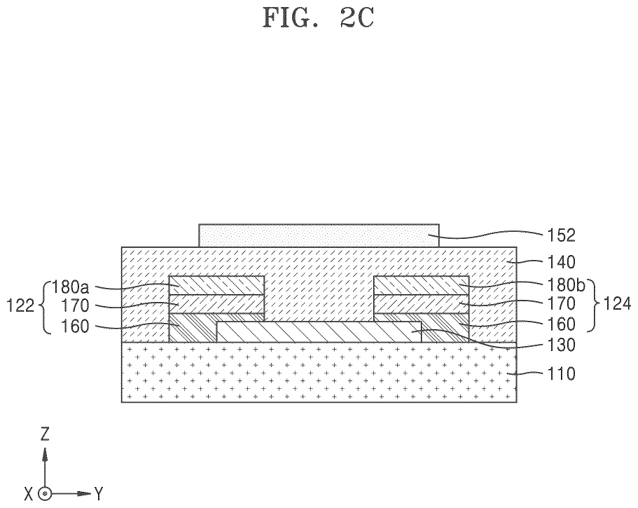

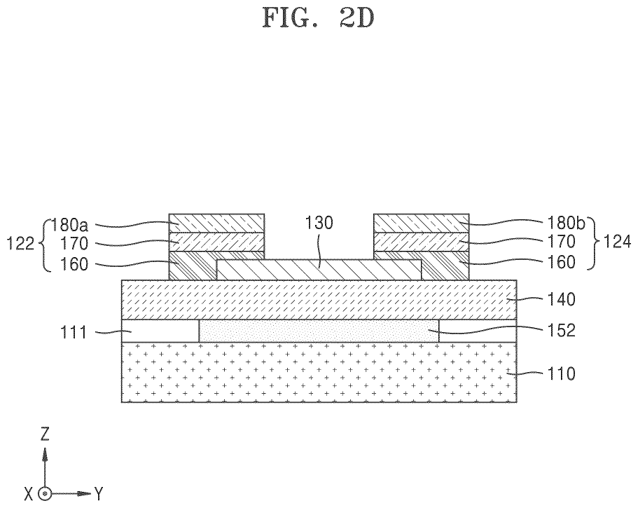

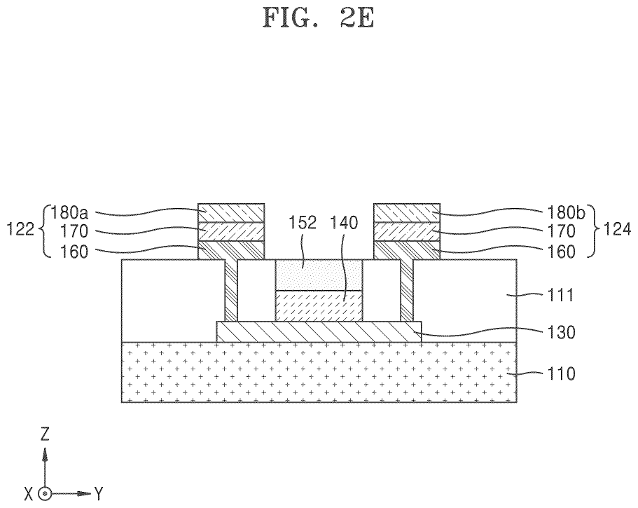

FIGS. 2A to 2E are respectively schematic cross-sectional views of various structures, which a field-effect transistor may have according to various example embodiments. FIGS. 2A and 2B are cross-sectional views of transistor structures allowing various example embodiments to be used in a bottom-contact-type oxide thin-film transistor (TFT). FIGS. 2C to 2E are cross-sectional views of transistor structures allowing various example embodiments to be used in a top-contact-type oxide TFT.

Referring to FIGS. 2A and 2B, the source structure 122 may be or include a structure in which the source electrode 180a, the conductive metal nitride film 170, and the IGTO film 160 are sequentially stacked. The drain structure 124 may have a structure in which the drain electrode 180b, the conductive metal nitride film 170, and the IGTO film 160 are sequentially stacked. The insulating barrier layer 111 may cover the opposite side surfaces and top surface of each of the source structure 122 and the drain structure 124. The IGTO film 160 in an upper portion of each of the source structure 122 and the drain structure 124 may be in contact with the oxide semiconductor layer 130 on the insulating barrier layer 111.

Referring to FIGS. 2C to 2E, the source structure 122 may be or include a structure in which the IGTO film 160, the conductive metal nitride film 170, and the source electrode 180a are sequentially stacked. The drain structure 124 may be or include a structure in which the IGTO film 160, the conductive metal nitride film 170, and the drain electrode 180b are sequentially stacked. The IGTO film 160 in a lower portion of each of the source structure 122 and the drain structure 124 may be in contact with the oxide semiconductor layer 130.

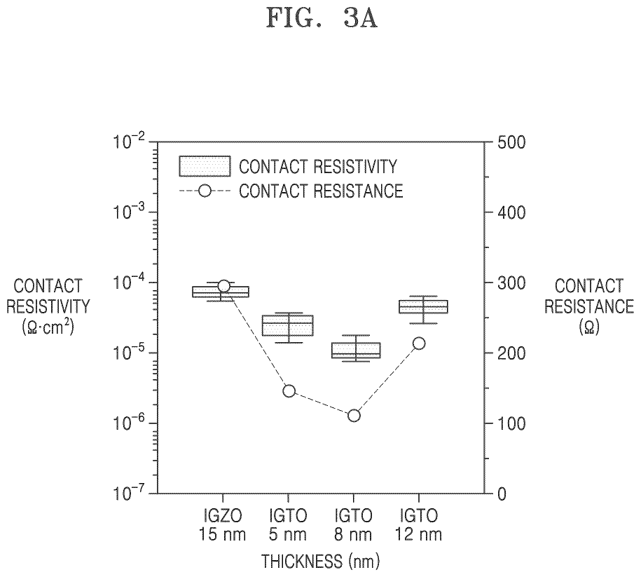

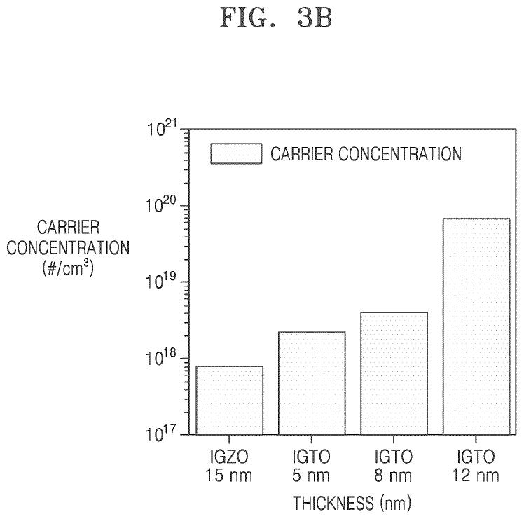

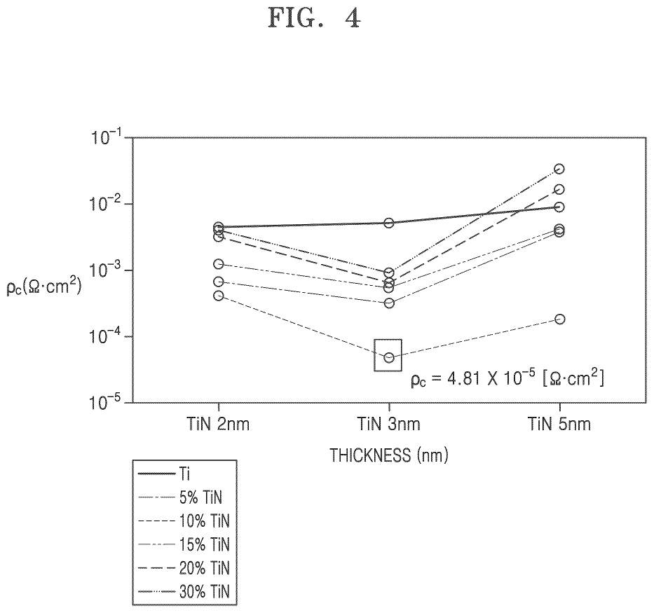

FIGS. 3A and 3B are graphs showing values of contact resistance, contact resistivity, and carrier concentration, which may be measured under process conditions of the IGTO film 160. FIG. 4 is a graph showing values of contact resistivity of the conductive metal nitride film 170, which may be measured with respect to the partial pressure of nitrogen and the thickness of a titanium nitride (TiN) film.

In some example embodiments, contact resistance, contact resistivity, and carrier concentrations may be measured based off of, for example, a four-point Kelvin contact. Alternatively or additionally, in some example embodiments, contact resistance, contact resistivity, and carrier concentrations may be measured off of, for example, a chain of contacts. However, example embodiments are not limited thereto.

Referring to FIG. 3A, when the thickness of the IGTO film 160 is about 5 nm to about 12 nm, the values of contact resistivity and contact resistance of the IGTO film 160 are lower than the values of a typical indium gallium zinc oxide (IGZO) film. In particular, it may be seen that when the thickness of the IGTO film 160 is 8 nm, the values of both the contact resistivity and the contact resistance of the IGTO film 160 are lowest among results of the measurement. It may also be seen that the carrier concentration is highest when the thickness of the IGTO film 160 is 12 nm and is second highest when the thickness of the IGTO film 160 is 8 nm. In embodiments, the IGTO film 160 having a higher electrical conductivity than the oxide semiconductor layer 130 may contribute to the reduction of the contact resistance of the field-effect transistor 100. The IGTO film 160 may be deposited in a process environment with a low partial pressure of oxygen by using one or more of sputtering, atomic layer deposition (ALD), or chemical vapor deposition (CVD). Referring to FIG. 3B, the values of carrier concentration may be checked when the carrier concentration is measured at different thicknesses of 5 nm, 8 nm, 12 nm, and 15 nm of the IGTO film 160. According to the graph of FIG. 3B, the carrier concentration is second highest when the thickness of the IGTO film 160 is 8 nm.

FIG. 4 shows results of measuring contact resistivity (pc) of the conductive metal nitride film 170 at different partial pressures of nitrogen and different thicknesses of the TiN film. TiN maintains stable properties at relatively high temperature and has strong reactivity with oxygen. Due to these characteristics of TiN, the TiN film may be effective in inducing an n+ layer therebelow by pulling oxygen from the IGTO film 160 in a lower portion of the field-effect transistor 100. FIG. 4 shows a result of measuring contact resistance while the thickness of the TiN film is changed from 2 nm to 3 nm and 5 nm under process conditions that 100 nm indium tin oxide is used as the material of the top capping layer 223 and the partial pressure of nitrogen is 10%, to determine optimal contact resistance conditions. According to the result of the measurement, when a TiN film having a thickness of 3 nm is used as the conductive metal nitride film 170, the contact resistivity is 4.81e-5 Ωcm² that is the lowest compared to when the thickness of the TiN film is 2 nm and 5 nm.

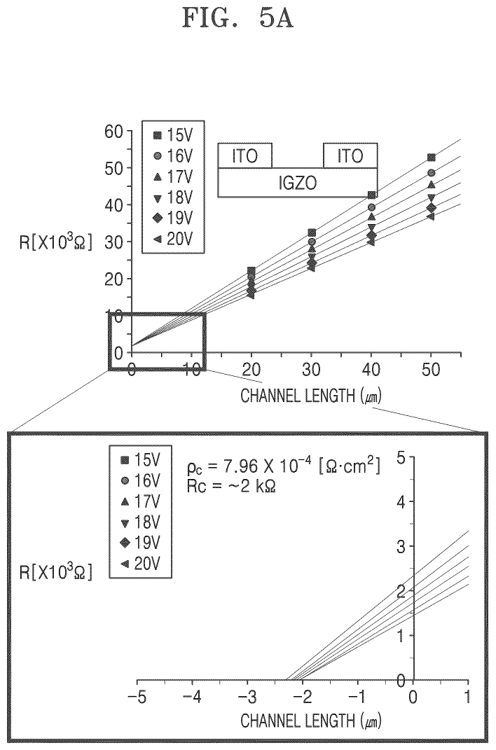

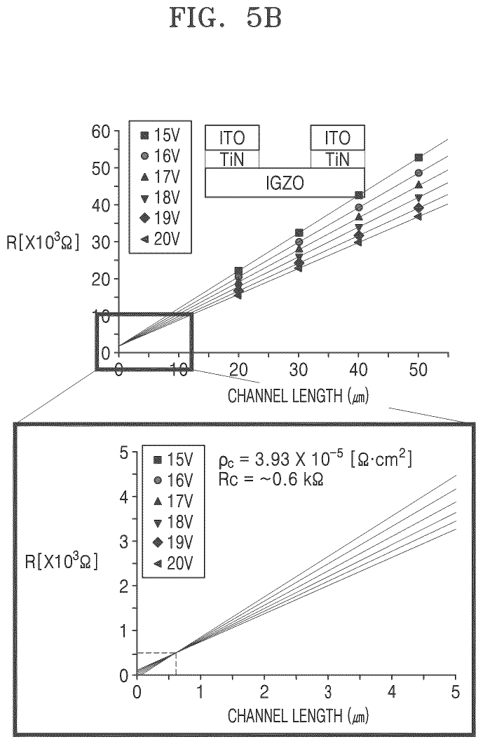

FIGS. 5A and 5B are respectively graphs showing results of measuring contact resistivity when a TiN film having a thickness of 3 nm is not inserted into any one of the source and drain structures 122 and 124, and when the TiN film is inserted into each of the source and drain structures 122 and 124. Referring to FIGS. 5A and 5B, it may be seen that when the TiN film is inserted, the contact resistivity is 3.93e-5 Ωcm² that is lower than a contact resistivity of 7.96e-4 Ωcm², which was measured when there is no TiN film.

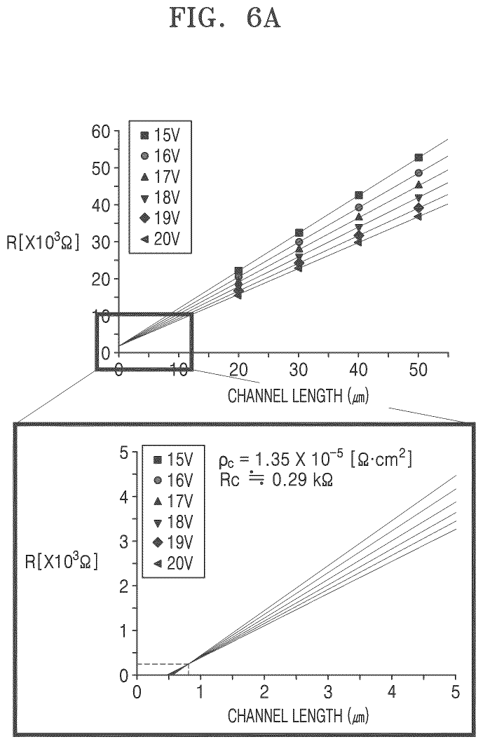

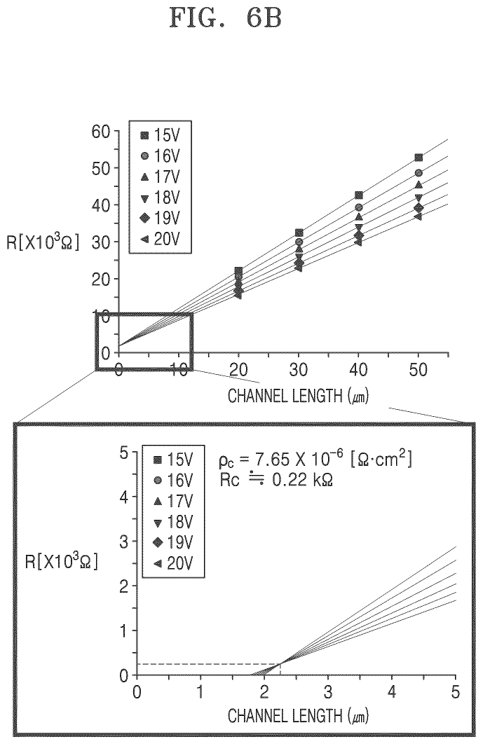

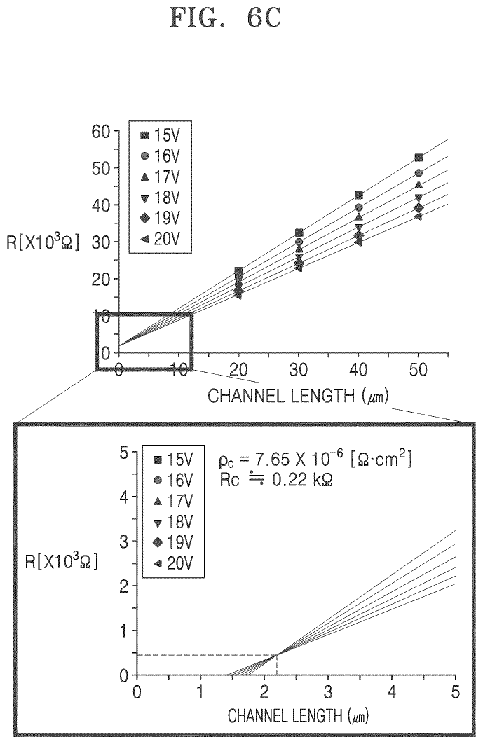

FIGS. 6A to 6C are respectively graphs showing results of measuring contact resistivity while the thickness of the IGTO film 160 is changed from 5 nm to 8 nm and 12 nm in each of the source and drain structures 122 and 124 having inserted thereinto a TiN film having a thickness of 3 nm. FIG. 6A shows that the contact resistivity is 1.35e-5 Ωcm² when the thickness of the IGTO film 160 is 5 nm. FIG. 6B shows that the contact resistivity is 7.65e-4 Ωcm² when the thickness of the IGTO film 160 is 8 nm. FIG. 6A shows that the contact resistivity is 2.64e-5 Ωcm² when the thickness of the IGTO film 160 is 12 nm. According to the results described above, it may be seen that the IGTO film 160 has contact resistivity of 10e⁻⁶ Ωcm² when the thickness of the IGTO film 160 is 8 nm. According to the results described above with reference to FIGS. 3A to 6C, it may be seen that the use of the IGTO film 160 having a thickness of 8 nm and the TiN conductive metal nitride film 170 having a thickness of 3 nm is an optimal condition for improving the contact resistance of the field-effect transistor 100.

According to various example embodiments, the field-effect transistor 100 may secure contact resistivity at a level of 10e⁻⁶ Ωcm² by inserting the IGTO film 160 and the conductive metal nitride film 170 between the oxide semiconductor layer 130 and the source electrode 180a or the drain electrode 180b, thereby improving contact resistance.

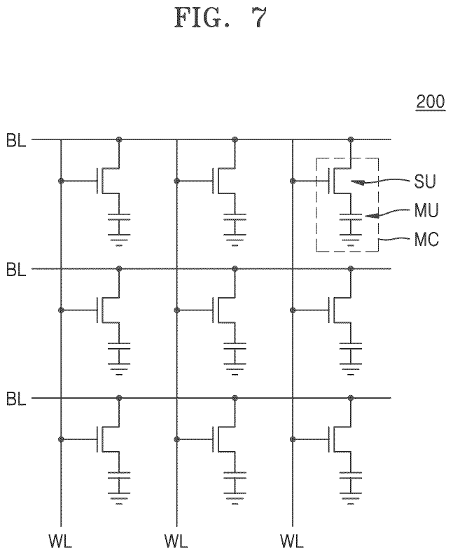

FIG. 7 is a schematic circuit diagram of an integrated circuit device 200 according to various example embodiments. Referring to FIG. 7, the integrated circuit device 200 may include a memory cell array including a plurality of memory cells MC. The circuit diagram of the integrated circuit device 200 of FIG. 7 is just an example, and various example embodiments are not limited thereto.

According to various example embodiments, each of the memory cells MC may include a memory unit MU and a selection unit SU. According to various example embodiments, the memory unit MU may be configured to store data. For example, the memory unit MU may include a capacitor configured to store charge. For example, a lower electrode of the memory unit MU may be grounded, and an upper electrode of the memory unit MU may be connected to the selection unit SU. In some example embodiments, the memory unit MU may alternatively or additionally include a memristor and/or a device other than a capacitor; example embodiments are not limited thereto.

According to various example embodiments, the selection unit SU may be configured to selectively control the movement of charge of the memory unit MU. According to various example embodiments, the selection unit SU may include the field-effect transistor 100. According to various example embodiments, the selection unit SU may selectively connect a bit line BL to the memory unit MU by controlling a word line WL.

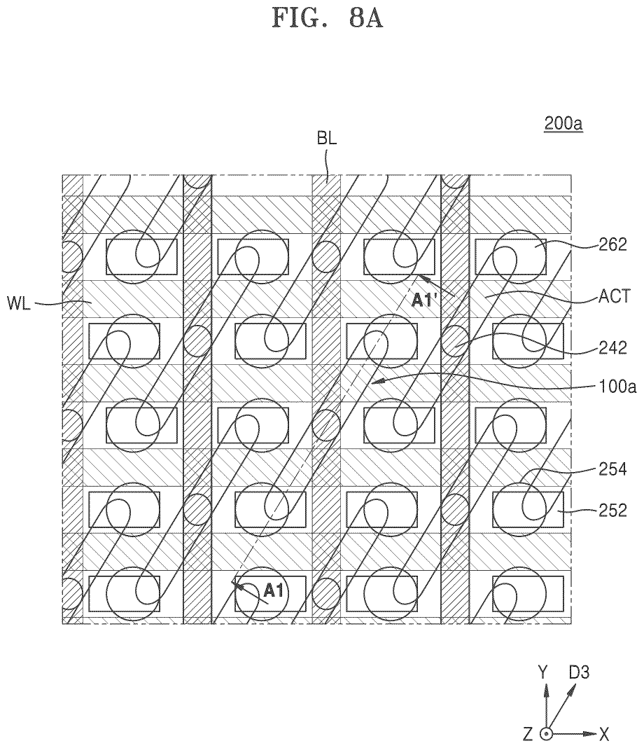

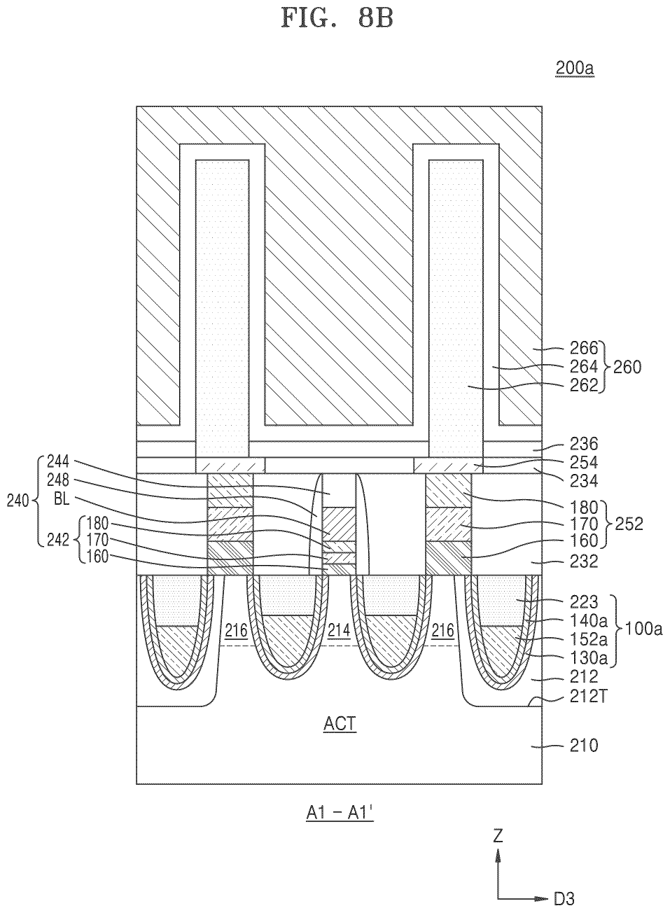

FIG. 8A is a layout diagram of a first integrated circuit device 200a according to some example embodiments.

According to various example embodiments, the first integrated circuit device 200a may include a first transistor structure 100a. According to various example embodiments, the first transistor structure 100a of the first integrated circuit device 200a may include a buried channel array transistor (BCAT). For example, the first transistor structure 100a may correspond to some example embodiments of the field-effect transistor 100 applied to the integrated circuit device 200.

Referring to FIG. 8A, a plurality of active regions ACT may be arranged in a third horizontal direction (a D3 direction) that is diagonal to a first horizontal direction (the X direction) and a second horizontal direction (the Y direction).

According to various example embodiments, a plurality of word lines WL may be parallel with each other and may extend in the first horizontal direction (the X direction) across the active regions ACT. According to various example embodiments, a plurality of bit lines BL may be above the word lines WL to be parallel with each other and may extend in the second horizontal direction (the Y direction) crossing the first horizontal direction (the X direction). According to various example embodiments, each of the bit lines BL may be connected to an active region ACT through a direct contact 242.

According to various example embodiments, a plurality of first capacitor contacts 252 may be between two adjacent bit lines BL. According to various example embodiments, the first capacitor contacts 252 may be arranged in lines in the first horizontal direction (the X direction) and the second horizontal direction (the Y direction). According to various example embodiments, a plurality of first conductive landing pads 254 may be respectively on the first capacitor contacts 252. For example, each of the first conductive landing pads 254 may at least partially overlap with one of the first conductive landing pads 254 in a vertical direction (the Z direction). According to various example embodiments, each of the first capacitor contacts 252 and each of the first conductive landing pads 254 may connect a first lower electrode 262 (in FIG. 8B) of a capacitor on one of the bit lines BL to one of the active regions ACT. FIG. 8B is a cross-sectional view taken along line A1-A1′ in FIG. 8A.

According to various example embodiments, the first integrated circuit device 200a may include a first semiconductor substrate 210 in which a plurality of active regions ACT are defined by a first isolation film 212. For example, the first isolation film 212 may be formed in a first isolation trench 212T formed in the first semiconductor substrate 210.

According to various example embodiments, the first semiconductor substrate 210 may include Si, Ge, or a semiconductor material, such as SiGe, SiC, GaAs, InAs, or InP. According to various example embodiments, the first semiconductor substrate 210 may include a conductive region, such as an impurity-doped well and/or an impurity-doped structure. According to various example embodiments, the first isolation film 212 may include an oxide film, a nitride film, or a combination thereof.

According to various example embodiments, a plurality of first word line trenches may extend in the first horizontal direction (the X direction) in the first semiconductor substrate 210. The first transistor structure 100a may be formed in each of the first word line trenches. According to various example embodiments, the first transistor structure 100a may include a first oxide semiconductor layer 130a, a first gate insulating layer 140a, a first gate electrode 152a, and a first top capping layer 223.

According to various example embodiments, the first oxide semiconductor layer 130a and the first gate insulating layer 140a may be sequentially formed in each a first word line trench. For example, the first oxide semiconductor layer 130a may conformally cover the inner wall of the first word line trench, and the first gate insulating layer 140a may be on the first oxide semiconductor layer 130a, thereby forming a second word line trench. According to various example embodiments, the first gate electrode 152a may be in the second word line trench, and the first top capping layer 223 may be on the first gate electrode 152a. For example, the first gate electrode 152a may correspond to a word line WL.

According to various example embodiments, the first top capping layer 223 may include indium tin oxide (ITO).

According to various example embodiments, the first gate electrode 152a, the first gate insulating layer 140a, and the first oxide semiconductor layer 130a of the first integrated circuit device 200a may respectively correspond to the gate electrode 152, the gate insulating layer 140, and the oxide semiconductor layer 130 of the field-effect transistor 100.

According to various example embodiments, a plurality of first transistor structures 100a may pass through a portion of an active region ACT. According to various example embodiments, an upper portion of the active region ACT may include a first source/drain region 214 and a second source/drain region 216, which are defined by the first transistor structures 100a. For example, each of the first source/drain region 214 and the second source/drain region 216 may include an impurity region doped with impurities or doped at a much higher concentration with impurities having a different conductivity type than impurities with which the active region ACT is doped. Each of the first source/drain region 214 and the second source/drain region 216 may independently include N-type or P-type impurities.

According to various example embodiments, a bit line structure 240 may extend in the second horizontal direction (the Y direction) on the first source/drain region 214. According to various example embodiments, the bit line structure 240 may include the direct contact 242, a bit line BL, a bit line capping layer 244, and a bit line spacer 248.

According to various example embodiments, a plurality of bit line contacts or direct contacts 242 may be respectively on a plurality of first source/drain regions 214, and the bit lines BL may be on the direct contacts 242 and may extend in the second horizontal direction (the Y direction). According to various example embodiments, the bit line capping layer 244 may be on the bit line BL. According to various example embodiments, the bit line spacer 248 may cover respective side walls of the direct contact 242, the bit line BL, and the bit line capping layer 244.

According to various example embodiments, the direct contact 242 may have a structure in which the IGTO film 160, the conductive metal nitride film 170, and the source or drain electrode 180a or 180b are sequentially stacked. At this time, the conductive metal nitride film 170 may include TiN or TaN. According to various example embodiments, the bit line BL may include doped polysilicon, Ti, TiN, TiSiN, W, WN, WSi, WSiN, Ru, or a combination thereof. According to various example embodiments, the bit line capping layer 244 may include ITO.

According to various example embodiments, a first interlayer insulating film 232 may be on the first semiconductor substrate 210 to surround the bit line structure 240. According to various example embodiments, a first capacitor contact 252 may pass through the first interlayer insulating film 232 and may be in contact with the second source/drain region 216.

According to various example embodiments, a second interlayer insulating film 234 may be on the bit line structure 240 and the first interlayer insulating film 232. According to various example embodiments, a first conductive landing pad 254 may pass through the second interlayer insulating film 234 and may be in contact with the first capacitor contact 252.

According to various example embodiments, the first capacitor contact 252 may have a structure in which the IGTO film 160, the conductive metal nitride film 170, and the source or drain electrode 180a or 180b are sequentially stacked. At this time, the conductive metal nitride film 170 may include TiN or TaN. According to various example embodiments, the first conductive landing pad 254 may include at least one selected from among or from the group consisting of metals, such as ruthenium (Ru), titanium (Ti), tantalum (Ta), niobium (Nb), iridium (Ir), molybdenum (Mo), and tungsten (W), and conductive metal nitrides, such as titanium nitride (TiN), tantalum nitride (TaN), niobium nitride (NbN), molybdenum nitride (MoN), and tungsten nitride (WN).

According to various example embodiments, a first capacitor structure 260 may be on the second interlayer insulating film 234. According to various example embodiments, the first capacitor structure 260 may include a first lower electrode 262 electrically connected to the first capacitor contact 252 by the first conductive landing pad 254, a first capacitor dielectric film 264 covering the first lower electrode 262, and a first upper electrode 266 separated from the first lower electrode 262 by the first capacitor dielectric film 264.

According to various example embodiments, each of the first lower electrode 262 and the first upper electrode 266 may include at least one selected from among or from the group consisting of metals, such as Ru, Ti, Ta, Nb, Ir, Mo, and W, conductive metal nitrides, such as TiN, TaN, NbN, MON, and WN, and conductive metal oxides, such as iridium oxide (IrO₂), ruthenium oxide (RuO₂), and strontium ruthenium oxide (SrRuO₃).

According to various example embodiments, the first capacitor dielectric film 264 may include at least one material selected from the group consisting of zirconium oxide, hafnium oxide, titanium oxide, niobium oxide, tantalum oxide, yttrium oxide, strontium titanium oxide, barium strontium titanium oxide, scandium oxide, and lanthanum oxide.

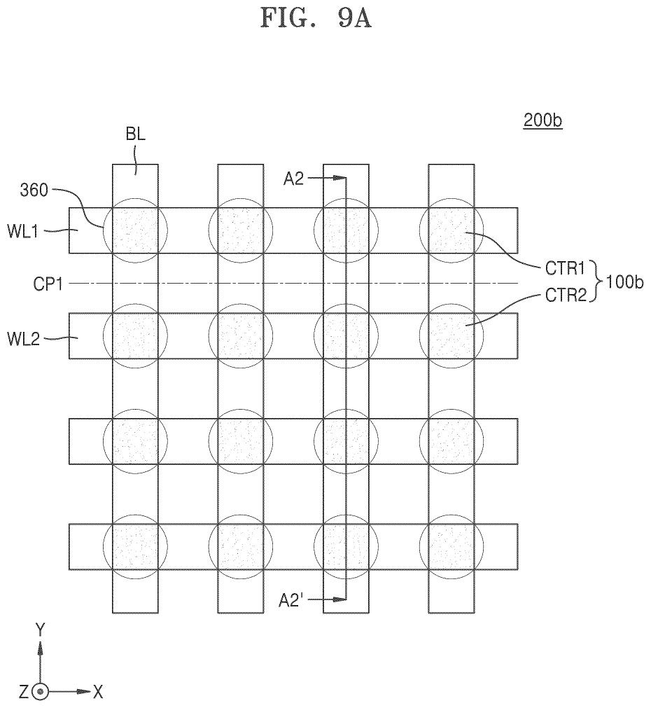

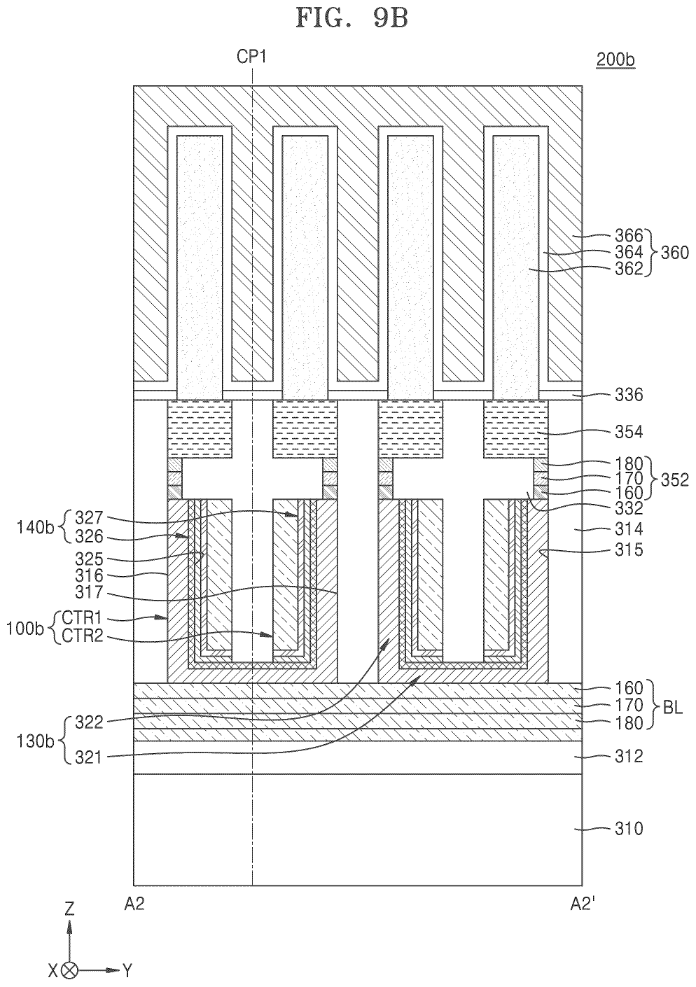

FIG. 9A is a layout diagram of a second integrated circuit device 200b according to some example embodiments. FIG. 9B is a cross-sectional view taken along line A2-A2′ in FIG. 9A.

Referring to FIGS. 9A and 9B, the second integrated circuit device 200b may include a second transistor structure 100b. According to various example embodiments, the second transistor structure 100b may correspond to a vertical transistor in which a channel extends in the vertical direction (the Z direction). Because the vertical transistor may occupy a smaller planar area than a planar transistor, the planar area of a memory cell MC may be reduced. Accordingly, the integration density of the second integrated circuit device 200b may increase.

According to various example embodiments, a plurality of word lines, e.g., first and second word lines WL1 and WL2, may extend in the first horizontal direction (the X direction) above a second semiconductor substrate 310 so as to be parallel with each other. According to various example embodiments, each of the word lines may be above a plurality of bit lines BL, and a plurality of second transistor structures 100b may be formed in portions in which the word lines overlap with the bit lines BL in the vertical direction (the Z direction).

According to various example embodiments, the word lines may include the first word line WL1 and the second word line WL2, which are alternately arranged in the second horizontal direction (the Y direction). Each of the second transistor structures 100b may include a first sub transistor structure CTR1 and a second sub transistor structure CTR2, which are alternately arranged in the second horizontal direction (the Y direction).

According to various example embodiments, the first sub transistor structure CTR1 may be arranged in mirror symmetry with the second sub transistor structure CTR2. For example, the first sub transistor structure CTR1 and the second sub transistor structure CTR2 may have a mirror symmetric structure with respect to a first central plane CP1 extending in the first horizontal direction (the X direction).

According to various example embodiments, a lower insulating layer 312 may be on the second semiconductor substrate 310. According to various example embodiments, the second semiconductor substrate 310 may include silicon including one or more of monocrystalline silicon, polycrystalline silicon, or amorphous silicon, and may or may not be doped. In some example embodiments, the second semiconductor substrate 310 may include at least one selected from the group consisting of Ge, SiGe, SiC, GaAs, InAs, and InP. In some example embodiments, the second semiconductor substrate 310 may include a conductive region, such as an impurity-doped well and/or an impurity-doped structure. According to various example embodiments, the lower insulating layer 312 may include an oxide film, a nitride film, or a combination thereof.

According to various example embodiments, a bit line BL may be on the lower insulating layer 312 and may extend in the second horizontal direction (the Y direction). Here, the bit line BL may include the same material as the bit line BL of the first integrated circuit device 200a.

According to various example embodiments, the bit line BL of the second integrated circuit device 200b may have a structure in which the source or drain electrode 180a or 180b, the conductive metal nitride film 170, and the IGTO film 160 are sequentially stacked. At this time, the conductive metal nitride film 170 may include TiN or TaN. A bit line insulating layer (not shown) may extend in the second horizontal direction (the Y direction) on a side wall of the bit line BL. For example, the bit line insulating layer may fill the space between two adjacent bit lines BL and have the same height as the bit lines BL.

According to various example embodiments, a mold layer 314 may be on the bit line BL and the bit line insulating layer. According to various example embodiments, the mold layer 314 may include a mold opening 315. Each second transistor structure 100b may be in the mold opening 315.

According to various example embodiments, a second oxide semiconductor layer 130b may be on the inner wall of the mold opening 315 and may have an oxide semiconductor layer opening 325. The second oxide semiconductor layer 130b may include a first part 321, which is in a bottom portion of the mold opening 315 and in contact with the bit line BL, and a second part 322, which is connected to the first part 321 and covers a first side wall 316 and a second side wall 317 of the mold opening 315. According to various example embodiments, the oxide semiconductor layer opening 325 may be defined by the first part 321 and the second part 322 of the second oxide semiconductor layer 130b. For example, the second oxide semiconductor layer 130b may have a U-shaped or a V-shaped vertical cross-section; however, example embodiments are not limited thereto.

According to various example embodiments, a second gate insulating layer 140b may be partially on the inner wall of the oxide semiconductor layer opening 325. According to various example embodiments, the second gate insulating layer 140b may include a first dielectric structure 326 and a second dielectric structure 327, which cover the second part 322 of the second oxide semiconductor layer 130b. For example, the first dielectric structure 326 may be in mirror symmetry with the second dielectric structure 327 with respect to the first central plane CP1. For example, the first dielectric structure 326 may be on a portion of the second part 322 of the second oxide semiconductor layer 130b, wherein the portion covers the first side wall 316 of the mold opening 315. For example, the second dielectric structure 327 may be on a portion of the second part 322 of the second oxide semiconductor layer 130b, wherein the portion covers the second side wall 317 of the mold opening 315. For example, each of the first dielectric structure 326 and the second dielectric structure 327 may partially cover the second part 322 of the second oxide semiconductor layer 130b. For example, the first dielectric structure 326 may be separated from the second dielectric structure 327 by an insulating structure 332 having the first central plane CP1 therein. For example, the first dielectric structure 326 may have an L-shaped vertical cross-section, and the second dielectric structure 327 may have a horizontally flipped L-shaped vertical cross-section.

According to various example embodiments, the first word line WL1 may be on the first dielectric structure 326, and the second word line WL2 may be on the second dielectric structure 327. The first word line WL1 and the second word line WL2 may be separated from the second part 322 of the second oxide semiconductor layer 130b by the first dielectric structure 326 and the second dielectric structure 327, respectively. According to various example embodiments, the first word line WL1 and the second word line WL2 may be separated from each other by the insulating structure 332.

According to various example embodiments, the first or second word line WL1 or WL2, the second gate insulating layer 140b, and the second oxide semiconductor layer 130b of the second integrated circuit device 200b may respectively correspond to the gate electrode 152, the gate insulating layer 140, and the oxide semiconductor layer 130 of the field-effect transistor 100.

According to various example embodiments, a second capacitor contact 352 may be on the second part 322 of the second oxide semiconductor layer 130b. According to various example embodiments, a plurality of second capacitor contacts 352 may be in contact respectively with the top surface of a portion of the second part 322 of the second oxide semiconductor layer 130b, which covers the first side wall 316 of the mold opening 315, and the top surface of a portion of the second part 322 of the second oxide semiconductor layer 130b, which covers the second side wall 317 of the mold opening 315. According to various example embodiments, a plurality of second capacitor contacts 352 may be arranged in lines in the first horizontal direction (the X direction) and the second horizontal direction (the Y direction).

According to various example embodiments, each of the second capacitor contacts 352 may have a structure in which the IGTO film 160, the conductive metal nitride film 170, and the source or drain electrode 180a or 180b are sequentially stacked. At this time, the conductive metal nitride film 170 may include TiN or TaN.

According to various example embodiments, a plurality of second landing pads 354 may be respectively on the second capacitor contacts 352. According to various example embodiments, at least a portion of each of the second landing pads 354 may overlap with one of the second capacitor contacts 352 in the vertical direction (the Z direction). According to various example embodiments, each second capacitor contact 352 and each second landing pad 354 may be surrounded by the mold layer 314 and the insulating structure 332.

According to various example embodiments, a second capacitor structure 360 may be on the mold layer 314 and the insulating structure 332. According to various example embodiments, the second capacitor structure 360 may include a second lower electrode 362 electrically connected to the second capacitor contact 352 by the second conductive landing pad 354, a second capacitor dielectric film 364 covering the second lower electrode 362, and a second upper electrode 366 separated from the second lower electrode 362 by the second capacitor dielectric film 364.

According to various example embodiments, the second lower electrode 362, the second capacitor dielectric film 364, and the second upper electrode 366 of the second capacitor structure 360 may respectively include the same materials as the first lower electrode 262, the first capacitor dielectric film 264, and the first upper electrode 266 of the first capacitor structure 260 of the first integrated circuit device 200a.

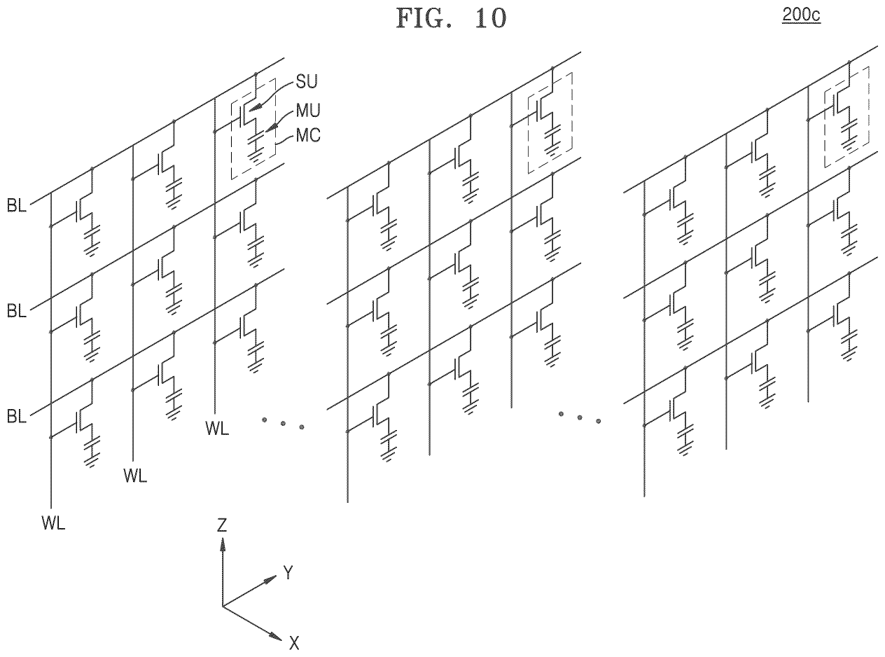

FIG. 10 is a schematic circuit diagram of a third integrated circuit device 200c according to some example embodiments.

Referring to FIG. 10, the third integrated circuit device 200c may have a structure in which memory cells are stacked in three dimensions. According to various example embodiments, a cell array of the third integrated circuit device 200c may include a plurality of sub cell arrays. The sub cell arrays may be arranged in the first horizontal direction (the X direction). Each sub cell array may include a plurality of memory cells MC, a plurality of bit lines BL, and a plurality of word lines WL. According to various example embodiments, each of the memory cells MC may include a memory unit MU and a selection unit SU.

For example, the memory cells MC, the bit lines BL, and the word lines WL may be considered as performing the same functions as those of the cell array in FIG. 7

According to various example embodiments, the bit lines BL may extend in the second horizontal direction (the Y direction) that crosses the first horizontal direction (the X direction) and may be arranged in parallel with each other in the vertical direction (the Z direction). According to various example embodiments, the word lines WL may extend in the vertical direction (the Z direction) and may be arranged in parallel with each other in the second horizontal direction (the Y direction).

While various example embodiments have been particularly shown and described with reference to various example embodiments thereof, it will be understood that various changes in form and details may be made therein without departing from the spirit and scope of the following claims.

What is claimed is:

1. A field-effect transistor comprising:
an insulating barrier layer on a substrate;
a gate electrode extending in one direction on the insulating barrier layer;
a gate insulating layer covering opposite side surfaces of and a top surface of the gate electrode;
an oxide semiconductor layer on the gate insulating layer and including at least one metal element selected from among indium (In) and zinc (Zn); and
a source structure and a drain structure separated from each other, the source structure and the drain structure being configured to be electrically connected to the oxide semiconductor layer,
wherein each of the source structure and the drain structure includes,
an indium gallium tin oxide (IGTO) film on the oxide semiconductor layer,
a conductive metal nitride film on the IGTO film,
one of a source electrode and a drain electrode on the conductive metal nitride film, and
a top capping layer on a top surface of the one of the source electrode and the drain electrode.

2. The field-effect transistor of claim 1, wherein a thickness of the IGTO film is 5 nm to 12 nm.

3. The field-effect transistor of claim 1, wherein the IGTO film has a tin concentration of at least 20 at %.

4. The field-effect transistor of claim 1, wherein the oxide semiconductor layer further includes gallium (Ga).

5. The field-effect transistor of claim 1, wherein the conductive metal nitride film includes at least one of titanium nitride (TiN) or tantalum nitride (TaN).

6. The field-effect transistor of claim 1, wherein a thickness of the conductive metal nitride film is 2 nm to 4 nm.

7. The field-effect transistor of claim 1, wherein the top capping layer includes indium tin oxide (ITO).

8. The field-effect transistor of claim 1, wherein the gate insulating layer includes silicon oxide (SiO₂).

9. An integrated circuit device comprising:
a substrate having a plurality active regions with a plurality of word line trenches defined in the substrate, the plurality of word line trenches extending in a first horizontal direction that is parallel with a top surface of the substrate;
a transistor structure on the substrate and including a source structure and a drain structure; and
a plurality of bit line structures on the substrate, the plurality of bit line structures extending in a second horizontal direction that is parallel with the top surface of the substrate and crosses the first horizontal direction,
wherein the transistor structure includes,
a gate insulating layer,
an oxide semiconductor layer on the gate insulating layer and including at least one metal element selected from among indium and zinc, and
a source structure and a drain structure separated from each other, the source structure and the drain structure being configured to be electrically connected to the oxide semiconductor layer,
wherein each of the source structure and the drain structure includes,
an indium gallium tin oxide (IGTO) film on the oxide semiconductor layer,
a conductive metal nitride film on the IGTO film,
one of a source electrode and a drain electrode on the conductive metal nitride film, and
a top capping layer on a top surface of the one of the source electrode and the drain electrode.

10. The integrated circuit device of claim 9, wherein a thickness of the IGTO film is 5 nm to 12 nm.

11. The integrated circuit device of claim 9, wherein the IGTO film has a tin content of at least 20 at %.

12. The integrated circuit device of claim 9, wherein the oxide semiconductor layer further includes gallium (Ga).

13. The integrated circuit device of claim 9, wherein the conductive metal nitride film includes at least one of titanium nitride or tantalum nitride.

14. The integrated circuit device of claim 9, wherein a thickness of the conductive metal nitride film is 2 nm to 4 nm.

15. The integrated circuit device of claim 9, wherein the top capping layer includes indium tin oxide.

16. The integrated circuit device of claim 9, wherein the gate insulating layer includes silicon oxide.

17. An integrated circuit device comprising:
a bit line extending in a first horizontal direction on a substrate;
a word line extending on the bit line in a second horizontal direction that crosses the first horizontal direction;
an oxide semiconductor layer including at least one metal element selected from among indium and zinc, the oxide semiconductor layer extending in a vertical direction on the bit line and being separated from the word line by a gate insulating layer;
a landing pad on the oxide semiconductor layer;
a capacitor structure on the landing pad; and
a transistor structure in an overlapping portion between the bit line and the word line,
wherein the transistor structure includes a source structure and a drain structure each having a sequential stack of an indium gallium tin oxide (IGTO) film, a conductive metal nitride film, one of a source electrode and a drain electrode, and a top capping layer.

18. The integrated circuit device of claim 17, wherein
a thickness of the IGTO film is 5 nm to 12 nm, and
a thickness of the conductive metal nitride film is 2 nm to 4 nm.

19. The integrated circuit device of claim 17, wherein the conductive metal nitride film includes at least one of titanium nitride or tantalum nitride.

20. The integrated circuit device of claim 17, wherein the oxide semiconductor layer further includes gallium.
